(19) United States
(12) Patent Application Publication
(10) Pub. No.: US 2012/0169910 A1
(43) Pub. Date: Jul. 5, 2012

(54) IMAGE SENSOR AND IMAGE CAPTURE DEVICE

(75) Inventor: Brahm Pal SINGH, Osaka (JP)

(73) Assignee: PANASONIC CORPORATION, Osaka (JP)

(21) Appl. No.: 13/415,941

(22) Filed: Mar. 9, 2012

Related U.S. Application Data
(63) Continuation of application No. PCT/JP2011/003933, filed on Jul. 8, 2011.

(30) Foreign Application Priority Data
Aug. 4, 2010 (JP) 2010-175542

(51) Int. Cl. H04N 5/335; H01L 27/146

(52) U.S. Cl. 348/302; 250/208.1; 348/E05.091

(57) ABSTRACT

In one embodiment of the present invention, an image capture device includes an image sensor 10 that includes: a photosensitive cell array 12 in which a plurality of photosensitive cells are arranged on an image capturing plane; a polarizer array 14 in which a plurality of unit structures, each including N polarizers (where N is an integer that is equal to or greater than two) that have mutually different polarization transmission axis directions, are arranged two-dimensionally and which is arranged so that light that has been transmitted through each polarizer is incident on its associated photosensitive cell; a circuit for reading a pixel signal from the photosensitive cell array 12; and a shifter 16 for shifting the polarizer array 14 with respect to the photosensitive cell array 12 parallel to the image capturing plane.

This is a continuation of International Application No. PCT/JP2011/003933, with an international filing date of Jul. 8, 2011, which claims priority of Japanese Patent Application No. 2010-175542, filed on Aug. 4, 2010, the contents of which are hereby incorporated by reference.

### BACKGROUND OF THE INVENTION

1. Field of the Invention

The present invention relates to an image sensor that can obtain polarization information and to an image capture device including such an image sensor.

2. Description of the Related Art

Recently, polarization imaging has attracted a lot of attention as a technique for obtaining information that could not be gotten only with an intensity image. In order to carry out polarization imaging, either polarizers or a polarizing plate needs to be arranged in front of the image capturing plane of an image sensor. Japanese Patent Application Laid-Open Publication No. 2007-86720 (Hereinafter, Patent Document No. 1) discloses an image sensor in which very small polarizers are arranged at a pitch of about 10.0 μm, for example. United States Patent Application Laid-Open Publication No. 2009-79982 (Hereinafter, Patent Document No. 2) discloses an image capture device that has a mechanism for rotating a polarizing plate. And Japanese Patent Application Laid-Open Publication No. 2003-47588 (Hereinafter, Patent Document No. 3) discloses an endoscope that obtains a polarization image by using alternately two polarizing plates, of which the polarization and transmission axes cross each other at right angles.

According to the conventional technique disclosed in Patent Document No. 1, the polarizers are fixed, and therefore, the problem of pixel shifting never arises and there is no need to provide any polarizer rotating mechanism, either. However, since only the light that has been transmitted through a polarization and transmission axis in a particular direction is incident on each pixel, signals supplied from multiple pixels should be used to obtain polarization information such as the degree of polarization and a polarization phase angle. As a result, the resolution decreases.

On the other hand, if the conventional technique disclosed in Patent Document No. 2 were adopted, the problem of pixel shifting would be caused by the rotating polarizing plate, and therefore, the resolution and the SNR would decrease. On top of that, it is difficult to reduce the size of such a device for rotating the polarizing plate.

Furthermore, according to the conventional technique disclosed in Patent Document No. 3, the polarizing plates should be moved a long distance and it is difficult to reduce the size of such a device that changes the positions of the polarizing plates.

It is therefore an object of the present invention to provide an image sensor that does not need such a device for rotating or moving greatly a polarizing plate and that can obtain polarization information from each pixel.

Another object of the present invention is to provide an image capture device such as a camera that includes such an image sensor and that can output polarization information.

### SUMMARY OF THE INVENTION

An image sensor according to the present invention includes: a photosensitive cell array in which a plurality of photosensitive cells are arranged on an image capturing plane; a polarizer array in which a plurality of unit structures, each including N polarizers (where N is an integer that is equal to or greater than two) that have mutually different polarization transmission axis directions, are arranged two-dimensionally and which is arranged so that light that has been transmitted through each said polarizer is incident on its associated photosensitive cell; a circuit that reads a pixel signal from the photosensitive cell array; and a shifter that shifts the polarizer array with respect to the photosensitive cell array parallel to the image capturing plane.

In one preferred embodiment, when an image is being captured, the shifter shifts the polarizer array by a distance that does not exceed the size of the unit structure.

In another preferred embodiment, when a stored electric charge signal is read from the entire photosensitive cell array, the shifter shifts the polarizer array on a pixel-by-pixel basis, thereby changing the polarization direction of light that is going to be incident on each said photosensitive cell.

In still another preferred embodiment, the image sensor performs the steps of: making light that has been transmitted through one of the N polarizers incident on each said photosensitive cell; and shifting the polarizer array on a pixel-by-pixel basis and then making light that has been transmitted through another one of the N polarizers incident on the photosensitive cell.

In yet another preferred embodiment, the actuator includes a first actuator portion that shifts the polarizer array in a first direction on a pixel-by-pixel basis and a second actuator portion that shifts the polarizer array in a second direction, which is perpendicular to the first direction, on a pixel-by-pixel basis, too. The actuator shifts the polarizer array periodically and two-dimensionally on the image capturing plane.

In a specific preferred embodiment, N is equal to or greater than three.

In yet another preferred embodiment, the shifter moves the polarizer array periodically and linearly on the image capturing plane.

In yet another preferred embodiment, the arrangement pitch of the polarizers in the polarizer array agrees with the arrangement pitch of the photosensitive cells in the photosensitive cell array.

In yet another preferred embodiment, each of the unit structures that form the polarizer array includes four polarizers, of which the polarization transmission axis directions are different from each other by 45 degrees.

In an alternative preferred embodiment, each of the unit structures that form the polarizer array includes three polarizers, of which the polarization transmission axis directions are different from each other by 60 degrees.

An image capture device according to the present invention includes: an image sensor that includes a photosensitive cell array in which a plurality of photosensitive cells are arranged on an image capturing plane, a polarizer array in which a plurality of unit structures, each including N polarizers (where N is an integer that is equal to or greater than two) that have mutually different polarization transmission axis directions, are arranged two-dimensionally and which is arranged so that light that has been transmitted through each said polarizer is incident on its associated photosensitive cell, and a shifter that shifts the polarizer array with respect to the photosensitive cell array parallel to the image capturing plane; a driver that drives the shifter; and a shooting lens that produces an image on the image sensor.

In one preferred embodiment, when a stored electric charge signal is read from the entire photosensitive cell array, the shifter shifts the polarizer array on a pixel-by-pixel basis, thereby changing the polarization direction of light that is going to be incident on each said photosensitive cell and obtaining luminance values of light rays that have been incident on respective photosensitive cells with mutually different polarization directions.

According to the present invention, as a shifter that shifts the polarizer array by a distance corresponding to the arrangement pitch of pixels parallel to the image capturing plane is used, there is no need to use a device of a big size to either rotate a polarizing plate or use two polarizing plates alternately. In addition, since light rays with mutually different polarization main axes can be incident on respective pixels, a polarization image with high resolution can be obtained.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 illustrates a general arrangement for an image capturing section of an image capture device as a first specific preferred embodiment of the present invention.

FIG. 2A schematically illustrates a planar layout of the polarizer array 14 of the first preferred embodiment and FIG. 2B schematically illustrates the arrangement of the photosensitive cell array 12.

FIG. 3A illustrates where one unit structure included in the polarizer array 14 at the initial position is located with respect to the photosensitive cell array 12.

FIG. 3B illustrates where the one unit structure included in the polarizer array 14 at the second position is located with respect to the photosensitive cell array 12.

FIG. 3C illustrates where the one unit structure included in the polarizer array 14 at the third position is located with respect to the photosensitive cell array 12.

FIG. 3D illustrates where the one unit structure included in the polarizer array 14 at the fourth position is located with respect to the photosensitive cell array 12.

FIG. 3E illustrates where the one unit structure included in the polarizer array 14 that has come back to the initial position is located with respect to the photosensitive cell array 12.

FIG. 4 illustrates a photosensitive cell array 12 that includes photosensitive cells that have a smaller size than polarizers in the polarizer array 14.

FIG. 5 indicates that each polarizer is given the sign A, B, C or D according to the direction of its polarization transmission axis.

FIG. 6 illustrates the correspondence between the polarizer array 14 and the arrangement of those signs A, B, C and D.

FIG. 7 illustrates an exemplary shift pattern of the polarizer array 14.

FIGS. 8A and 8B are respectively a top view of an image sensor 10 to which the shifter 16 has been attached and a cross-sectional view of the image sensor 10 shown in FIG. 8A as viewed on the plane B-B′.

Portions (a) through (d) of FIG. 9 show how the shifter 16 shown in FIG. 8 operates.

FIG. 10 is a diagram showing an exemplary waveform of the voltages applied to piezoelectric transducers 160a, 160b, 160c and 160d when the series of shift operations shown in FIG. 9 are performed.

FIG. 11 is a top view illustrating a movable polarizer unit 1000 in which the shifter 16 and the polarizer array 14 are integrated together.

Portions (a), (b) and (c) of FIG. 12 are top views of a base 1002, the polarizer array 14 and a linear actuator 1004a, respectively. Portion (d) of FIG. 12 illustrates an X direction shifting stage 1010. And portion (e) of FIG. 12 is a cross-sectional view of the X direction shifting stage shown in portion (d) of FIG. 12 as viewed on the plane E-E′.

FIG. 13 illustrates the X direction shifting stage 1010, a base 1001, and the linear actuator 1004a.

FIG. 14 is a top view illustrating another exemplary arrangement for a movable polarizer unit 1000 in which the shifter 16 and the polarizer array 14 are integrated together.

FIG. 15 is a block diagram illustrating a general configuration for an image capture device as a preferred embodiment of the present invention.

FIG. 16 is a block diagram illustrating an exemplary combination of major components of the signal processing section 200 of this preferred embodiment.

FIG. 17 is a graph showing the intensities (either pixel values or luminances) I₁ through I₄ of the light rays that have been transmitted through four kinds of polarizers, of which the polarization transmission axes (with Ψi=0, 45, 90, and 135 degrees, respectively) are defined in four different directions.

FIG. 18 is a graph showing the amplitude, phase and average of the curve showing a variation in polarized light intensity.

FIG. 19 is a top view illustrating the arrangement of a polarizer array according to a second preferred embodiment of the present invention.

FIG. 20A illustrates a part of the polarizer array shown in FIG. 19 and FIG. 20B illustrates an alternative arrangement pattern of polarizers.

FIG. 21 schematically illustrates an exemplary planar layout for the polarizer array 21 of the second preferred embodiment of the present invention.

FIGS. 22A and 22B show how to shift a polarizer array 14, each row of which includes four different kinds of polarizers 14A, 14B, 14C and 14D, on a pixel-by-pixel basis.

FIGS. 23A and 23B show how to shift the polarizer array 14, each row of which includes four different kinds of polarizers 14A, 14B, 14C and 14D, on a pixel-by-pixel basis.

FIG. 24 is a diagram showing how the voltage applied to the actuator varies while the series of shift operations shown in FIGS. 22 and 23 are performed.

FIG. 25 illustrates how to shift, within an XY plane, a polarizer array 14 where three kinds of polarizers 14A, 14B and 14C are arranged.

FIGS. 26A through 26C illustrate an example in which a polarizer array 14 where three kinds of polarizers 14A, 14B and 14C are arranged is shifted only in the X-axis direction.

FIG. 27 shows an exemplary waveform of the voltage applied to the actuator when the operations shown in FIG. 26 are performed.

FIG. 28 illustrates an exemplary circuit configuration for the photosensitive cell array 12 shown in FIG. 2B.

FIG. 29 schematically shows the respective electric charge storage periods in the photosensitive cell array 12.

### DETAILED DESCRIPTION OF PREFERRED EMBODIMENTS

### Embodiment 1

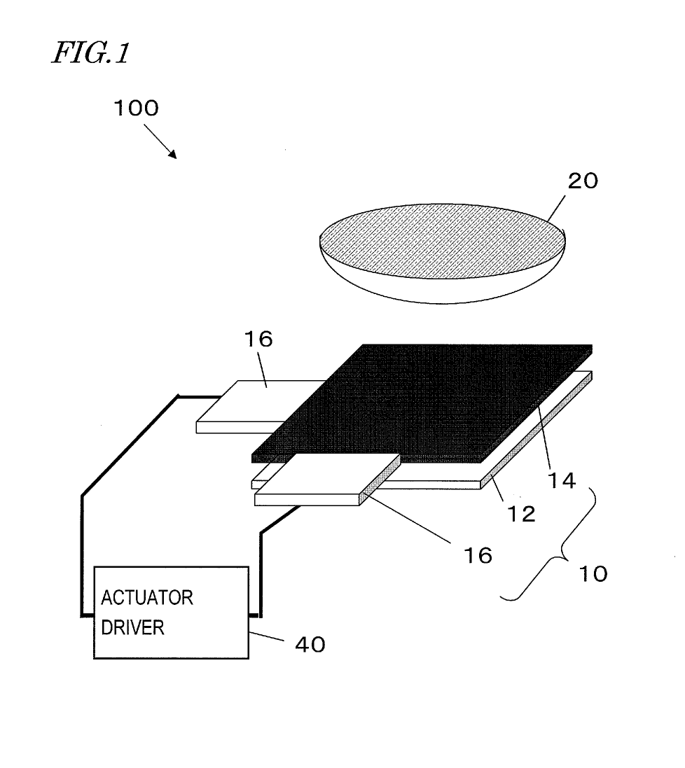

First of all, take a look at FIG. 1, which illustrates a general arrangement for an image capturing section of an image capture device as a first specific preferred embodiment of the present invention.

This image capturing section 100 includes an imager (i.e., image sensor) 10 and a shooting lens 20 for producing an image on the image capturing plane of the image sensor 10. Specifically, the image sensor 10 includes a photosensitive cell array 12 in which a plurality of photosensitive cells (i.e., photoelectric transducers) are arranged on the image capturing plane, a polarizer array (i.e., a polarization mosaic array plate) 14, and a shifter 16 for shifting the polarizer array 14 with respect to the photosensitive cell array 12 parallel to the image capturing plane.

The respective photosensitive cells correspond to pixels, and the photosensitive cell array 12 may also be called a “pixel array 12”. As will be described in detail later, a plurality of unit structures, each including N polarizers (where N is an integer that is equal to or greater than two) that have mutually different polarization transmission axis directions, are arranged two-dimensionally in the polarizer array 14. And the polarizer array 14 is arranged so that light that has been transmitted through each polarizer is incident on its associated photosensitive cell. The shooting lens 20 is schematically illustrated as a single lens in FIG. 1, but ordinarily is implemented as an optical system including multiple lenses in combination and has a known arrangement.

The image capturing section 100 further includes an actuator driver 40 for driving an actuator that the shifter 16 has. The actuator driver 40 may be either built in the image sensor 10 or provided as a separate part.

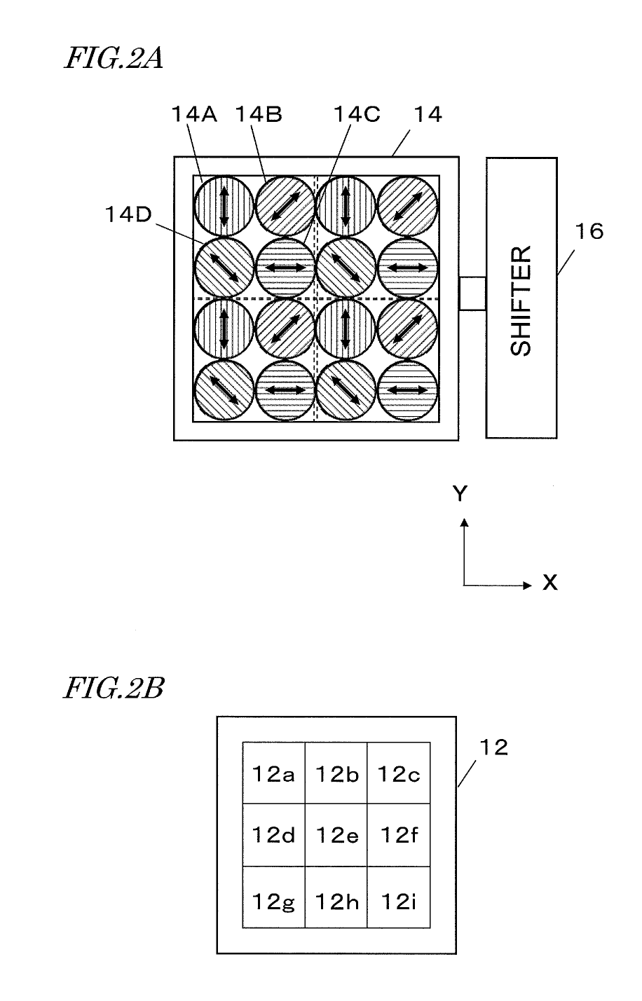

Turn to FIGS. 2A and 2B next.

FIG. 2A schematically illustrates a planar layout of the polarizer array 14 and FIG. 2B schematically illustrates the arrangement of the photosensitive cell array 12.

In the polarizer array 14 shown in FIG. 2A, four unit structures, each of which includes four polarizers 14A, 14B, 14C and 14D that have mutually different polarization transmission axis directions, are arranged two-dimensionally. Although a lot more unit structures are actually arranged in the polarizer array 14, only four unit structures are illustrated in FIGS. 2A and 2B for the sake of simplicity. The respective polarizers 14A, 14B, 14C and 14D shown in FIG. 2A have four arrows that point mutually different directions. These arrows indicate the polarization transmission axis directions (i.e., principal axis directions) of the polarizers. Only part of light that has been incident on each polarizer can be transmitted through that polarizer if the vibration direction of its electric vector agrees with the polarization transmission axis. The light that has been transmitted through a polarizer is linearly polarized light that is polarized in the polarization transmission axis direction of that polarizer.

In FIG. 2B, only nine (=three rows×three columns) photosensitive cells 12a, 12b, . . . and 12i are illustrated for the sake of simplicity. Actually, however, a huge number of (e.g., more than one million) photosensitive cells are arranged in the photosensitive cell array 12. The arrangement pitch of the photosensitive cells in the photosensitive cell array 12 agrees with that of the polarizers in the polarizer array 14. And these arrangement pitches will be sometimes referred to herein as a “pixel pitch”. The photosensitive cell array 12 is actually arranged so as to receive the light that has been transmitted through the respective polarizers of the polarizer array 14 as described above. The photosensitive cell array 12 is made up of photosensitive cells that are arranged in columns and rows.

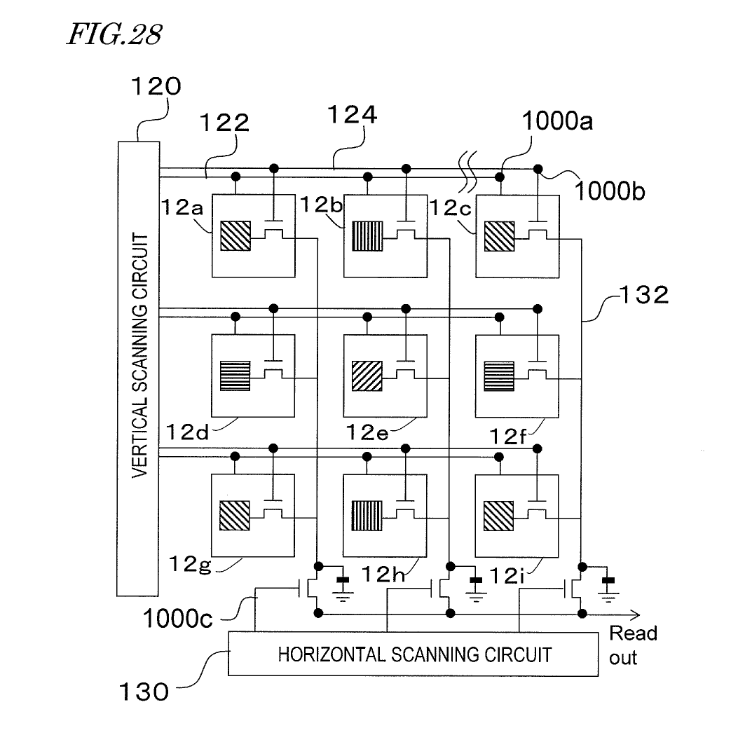

FIG. 28 illustrates an exemplary circuit configuration for the photosensitive cell array 12 shown in FIG. 2b. Specifically, in FIG. 28, illustrated are 3×3 photosensitive cells 12a through 12i, control signal lines 122 and 124 and an output signal line 132 that are connected to these photosensitive cells 12a through 12i, and so on. As described above, the photosensitive cell array 12 actually includes a huge number of photosensitive cells (not shown).

Outside of the area where these photosensitive cells 12a through 12i are arranged, provided are a vertical scanning circuit 120 and a horizontal scanning circuit 130 as circuits that read signals from the photosensitive cell array 12. First and second control signal lines 122 and 124 are connected to the vertical scanning circuit 120, which outputs a control signal 1000a that specifies the timing to start storing electric charge to the first control signal line 122 and which also outputs a control signal 1000b that specifies the timing to read the stored electric charge signal to the second control signal line 124.

The control signal 1000a that has been output from the vertical scanning circuit 120 to the first control signal line 122 is supplied to the reset element (not shown) of each of the photosensitive cells 12a through 12i. When the control signal 1000a is supplied to a reset element, the electric charge that has been stored in the photosensitive cell associated with that reset element is cleared and the electric charge storage state of the photosensitive cell is reset. As a result, another electric charge storage period begins.

On the other hand, the control signal 1000b that has been output from the vertical scanning circuit 120 to the control signal line 124 is supplied to the gate of the read transistor of any of the photosensitive cells 12a through 12i, thereby controlling the ON and OFF states of that transistor. Specifically, when the control signal 1000b is supplied to the gate of a transistor, that transistor turns ON and an electrical signal, representing the quantity of electric charge that has been stored in any of the photosensitive cells 12a through 12i, is output to the output signal line 132. The electrical signals on the output signal line 132 are sequentially read out one pixel after another in accordance with the control signal 1000c supplied from the horizontal scanning circuit 130.

That is to say, after the electric charge that has been stored in a particular row of photosensitive cells, e.g., the photosensitive cells 12a, 12b and 12c that form the first row in FIG. 28, has been read out, the electric charge that has been stored in the next row of photosensitive cells, e.g., the photosensitive cells 12d, 12e and 12f that form the second row in FIG. 28, is read out.

In one preferred embodiment, the control signal 1000a is supplied substantially simultaneously to all photosensitive cells that form a single row, thereby resetting those photosensitive cells. When a predetermined electric charge storage period passes after that reset, the control signal 1000b is supplied substantially simultaneously to all of those photosensitive cells that form that row. As a result, the stored electric charge signals are supplied from the photosensitive cells that form that row onto the signal line 132. After that, the stored electric charge signals supplied from that row of photosensitive cells are sequentially read out in accordance with the control signal 1000c.

By sequentially performing this read operation on one row after another, the stored electric charge signal can be obtained from every photosensitive cell in the photosensitive cell array 12. In order to make the electric charge storage periods of all of those photosensitive cells substantially equal to each other, the interval between the application of the control signal (i.e., the reset signal) 1000a and that of the control signal (i.e., the read signal) 1000b needs to have the same length for each and every row.

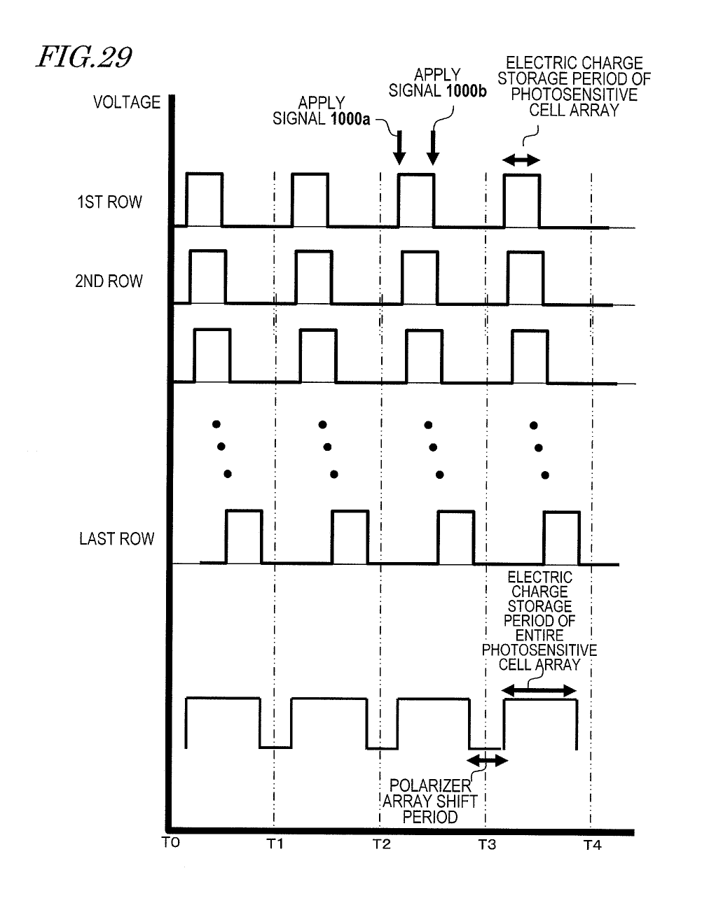

FIG. 29 schematically shows the respective electric charge storage periods of representative ones of the first through last rows of the photosensitive cell array 12. In each of these rows, the interval between the application of the control signal 1000a and that of the control signal 1000b corresponds to the electric charge storage period. Since the timing to apply the control signal 1000b varies from one row to another, the signals that have been read out from multiple rows of photosensitive cells never run into each other on the same output signal line.

At the bottom of FIG. 29, illustrated is the electric charge storage period of the entire photosensitive cell array 12 as the combination of the respective electric charge storage periods of all of those rows. As will be described later, when the stored electric charge signal is read from the entire photosensitive cell array 12, the polarizer array 14 is shifted two-dimensionally. That is to say, typically, after the stored electric charge signal has been read out from the entire photosensitive cell array 12 and before the next electric charge storage period begins in the photosensitive cell array 12, the polarizer array 14 is moved two-dimensionally. Strictly speaking, the polarizer array 14 may be shifted anytime unless the polarizer array 14 is moved during the electric charge storage period of any photosensitive cell. That is to say, the polarizer array 14 may be shifted while no charge is being stored anywhere in the photosensitive cell array 12.

Now look at FIG. 2A again. The polarizer array 14 is shifted by the shifter 16 parallel to the paper on which FIG. 2A is drawn, i.e., parallel to the plane that is defined by the X- and Y-axis directions of the XY coordinate system. The shifter 16 positions the polarizer array 14 so that the light that has been transmitted through each polarizer of the polarizer array 14 is incident on an associated one of the photosensitive cells. In FIG. 2A, the shifter 16 is supposed to be located only on the right-hand side of the polarizer array 14 for the sake of simplicity. Actually, however, the shifter 16 does not have to be arranged in this manner. The configuration and operation of the shifter 16 will be described in detail later.

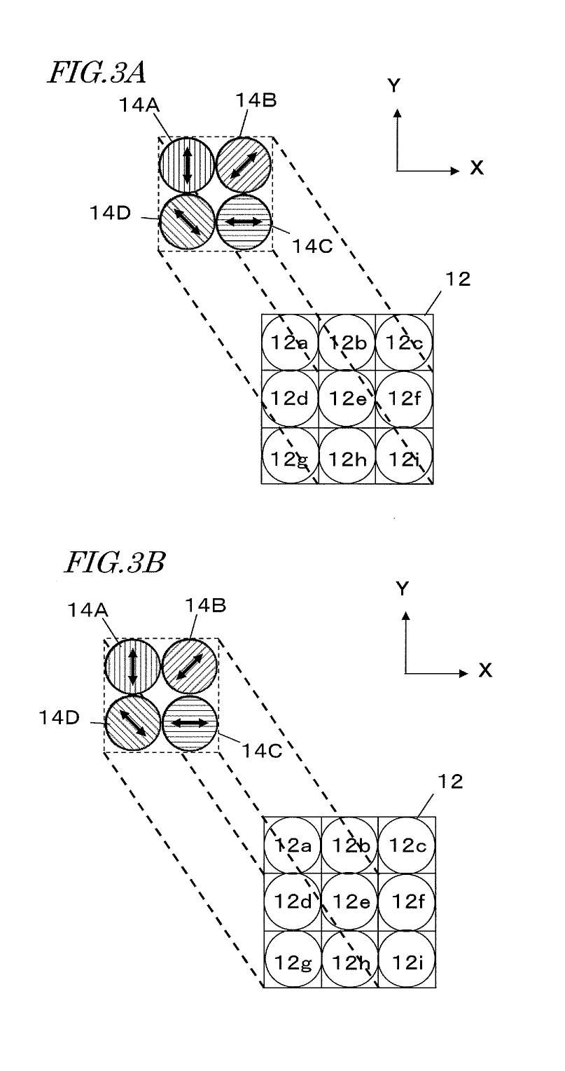

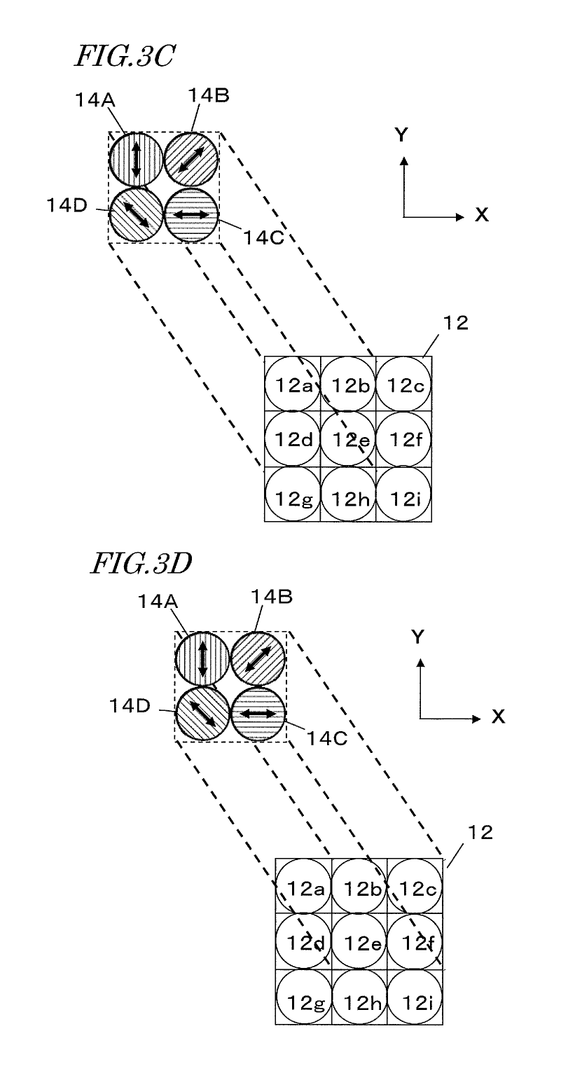

Next, it will be described with reference to FIGS. 3A through 3E how the polarizer array 14 may be shifted with respect to the photosensitive cell array 12.

First of all, take a look at FIG. 3A.

FIG. 3A illustrates where one unit structure included in the polarizer array 14 at the initial position is located with respect to the photosensitive cell array 12. At this initial position, the light rays that have been transmitted through the four polarizers 14A, 14B, 14C and 14D are incident on the photosensitive cells 12e, 12f, 12i and 12h, respectively. In this manner, light rays with mutually different polarization directions are incident at the same time on these photosensitive cells 12e, 12f, 12i and 12h.

While the polarizer array 14 is located at this initial position, the photosensitive cells 12e, 12f, 12i and 12h make photoelectric conversion, thereby producing and storing electric charge according to the quantity of the light received. And when a predetermined electric charge storage period passes, the electric charge that has been stored in each of these photosensitive cells 12e, 12f, 12i and 12h is read out as a pixel signal (i.e., a stored electric charge signal). This signal represents the luminance value of light that is polarized in a particular direction. After the electric charge has been read out, the stored charge will be reset. In general, the electric charge storage period is defined by the inverse number of a signal reading frame rate (in frames per second (fps)).

Look at FIG. 3B next.

FIG. 3B illustrates where one unit structure included in the polarizer array 14 at the next position is located with respect to the photosensitive cell array 12. At this position, the light rays that have been transmitted through the four polarizers 14A, 14B, 14C and 14D are incident on the photosensitive cells 12d, 12e, 12h and 12g, respectively. The polarizer array 14 shown in FIG. 3B has been shifted by one pixel from its initial position (shown in FIG. 3A) in the −X-axis direction by the shifter 16 shown in FIG. 2A.

While the polarizer array 14 is located at the position shown in FIG. 3B, the photosensitive cells 12d, 12e, 12h and 12g make photoelectric conversion, thereby producing and storing electric charge according to the quantity of the light received. And when a predetermined electric charge storage period passes, the electric charge that has been stored in each of these photosensitive cells 12d, 12e, 12h and 12g is read out as a pixel signal. After the electric charge has been read out, the stored charge will be reset.

Take the photosensitive cell 12h as an example. When the polarizer array 14 was located at the position shown in FIG. 3A, the light ray transmitted through the polarizer 14D was incident on the photosensitive cell 12h. And when the polarizer array 14 is located at the position shown in FIG. 3B, the light ray transmitted through the polarizer 14C is incident on the photosensitive cell 12h.

Since the polarizer array 14 is shifted (i.e., translated by one pixel) when a pixel signal (i.e., stored electric charge signal) is read from the entire photosensitive cell array 12, the polarization direction of the light incident on each photosensitive cell does not change during an electric charge storage period. As a result, information about the polarization of the light incident on the photosensitive cell can be obtained based on the pixel signal that has been read. It will be described in detail later exactly how to obtain the polarization information on a pixel-by-pixel basis.

Now turn to FIG. 3C.

FIG. 3C illustrates where one unit structure included in the polarizer array 14 at the next position is located with respect to the photosensitive cell array 12. At this position, the light rays that have been transmitted through the four polarizers 14A, 14B, 14C and 14D are incident on the photosensitive cells 12a, 12b, 12e and 12d, respectively. The polarizer array 14 shown in FIG. 3C has been shifted by one pixel from the position shown in FIG. 3B in the +Y-axis direction by the shifter 16 shown in FIG. 2A.

While the polarizer array 14 is located at the position shown in FIG. 3C, the photosensitive cells 12a, 12b, 12e and 12d make photoelectric conversion, thereby producing and storing electric charge according to the quantity of the light received. And when a predetermined electric charge storage period passes, the electric charge that has been stored in each of these photosensitive cells 12a, 12b, 12e and 12d is read out as a pixel signal. After the electric charge has been read out, the stored charge will be reset.

Take a look at FIG. 3D next.

FIG. 3D illustrates where one unit structure included in the polarizer array 14 at the next position is located with respect to the photosensitive cell array 12. At this position, the light rays that have been transmitted through the four polarizers 14A, 14B, 14C and 14D are incident on the photosensitive cells 12b, 12c, 12f and 12e, respectively. The polarizer array 14 shown in FIG. 3D has been shifted by one pixel from the position shown in FIG. 3C by the shifter 16 shown in FIG. 2A.

While the polarizer array 14 is located at the position shown in FIG. 3D, the photosensitive cells 12b, 12c, 12f and 12e make photoelectric conversion, thereby producing and storing electric charge according to the quantity of the light received. And when a predetermined electric charge storage period passes, the electric charge that has been stored in each of these photosensitive cells 12b, 12c, 12f and 12e is read out as a pixel signal. After the electric charge has been read out, the stored charge will be reset.

Now turn to FIG. 3E.

FIG. 3E illustrates where one unit structure included in the polarizer array 14 at the next position is located with respect to the photosensitive cell array 12. At this position, their relative arrangement is the same as what is illustrated in FIG. 3A and the same operation as what has already been described with reference to FIG. 3A is carried out once again.

As described above, according to this preferred embodiment, the polarizer array 14 changes its position from the one shown in FIG. 3A into the ones shown in FIGS. 3B, 3C and 3D in this order, and then goes back to the position shown in FIG. 3A as shown in FIG. 3E. When these periodic operations are repeatedly performed, light rays that have been transmitted through four polarizers that have mutually different polarization transmission axes are sequentially incident on each photosensitive cell during one period. Since the pixel signal is read out synchronously with the two-dimensional movement of the polarizer array 14, the polarization information can be obtained.

Although every polarizer and every photosensitive cell shown in FIGS. 3A through 3E have a circular planar shape, this is just an example and the polarizers and photosensitive cells (i.e., light receiving areas) do not have to have such a circular planar shape. The planar shapes and sizes of the polarizers and photosensitive cells are determined to make the light that has been transmitted through each polarizer incident efficiently on its associated photosensitive cell and to prevent a light ray that has not been transmitted through an associated polarizer from being incident on each photosensitive cell.

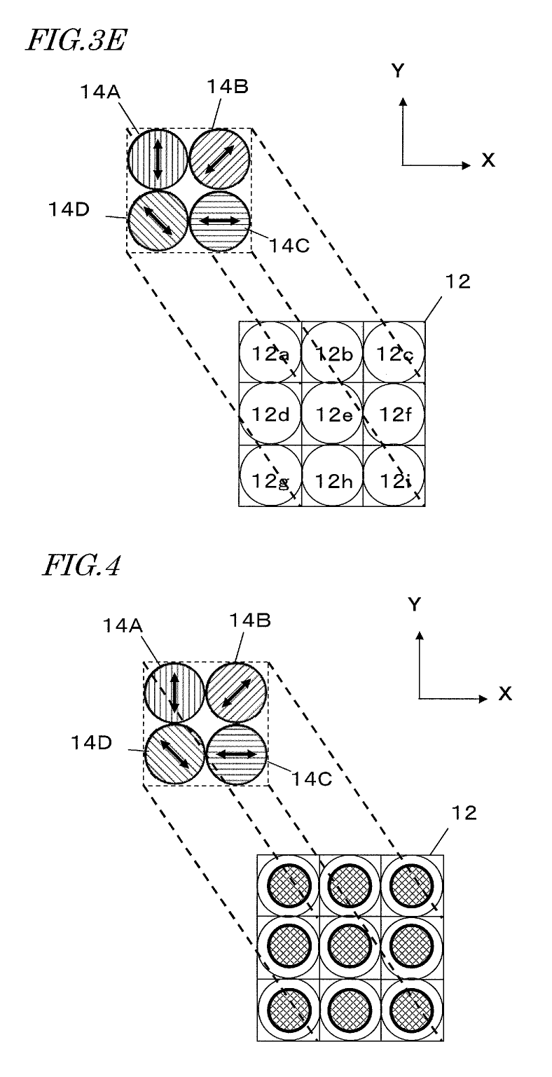

In FIG. 4, the photosensitive cells are illustrated as having a smaller size than the polarizers. Considering the magnitude of misalignment of the polarizer array 14, it is preferred that the photosensitive cells be designed to have a smaller size than the polarizers. As long as the photosensitive cells are entirely covered with the polarizers, the photosensitive cells do not have to have a circular planar shape but may also have an elliptical or polygonal planar shape. The same can be said about the planar shape of the polarizers, which does not have to be circular but may also be elliptical or polygonal, too. For example, if two kinds of polarizers, of which the polarization transmission axis directions intersect with each other at right angles, are arranged, each polarizer may also have a square or octagonal planar shape. Generally speaking, if the polarization transmission axes point N different directions, the polarizers preferably have a planar shape that is symmetric when rotated (360/N) degrees on the center axis.

Optionally, the photosensitive cell may be covered with a micro lens. Or the photosensitive cell array 14 could be implemented by a backside illumination type image sensor. Meanwhile, if the photosensitive cell array 14 is implemented by a normal surface illumination type image sensor, wiring (not shown) should be arranged between the photosensitive cells shown in FIG. 4.

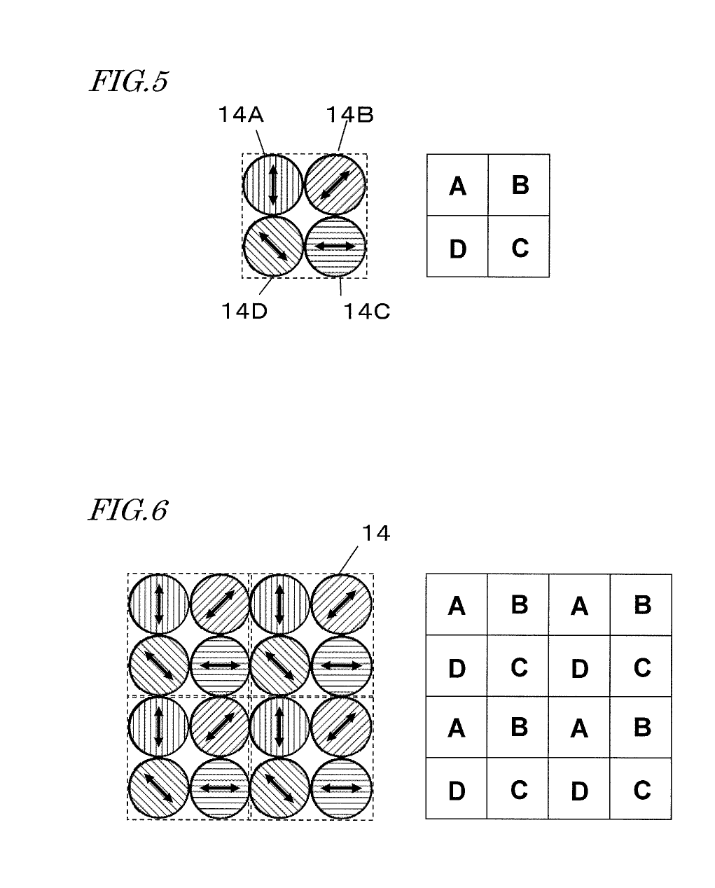

Next, look at FIG. 5. As shown in FIG. 5, each polarizer will be identified herein by the sign A, B, C or D according to the direction of its polarization transmission axis. Using these signs, the polarizer array 14 shown on the left-hand side of FIG. 6 can be simply illustrated as shown on the right-hand side.

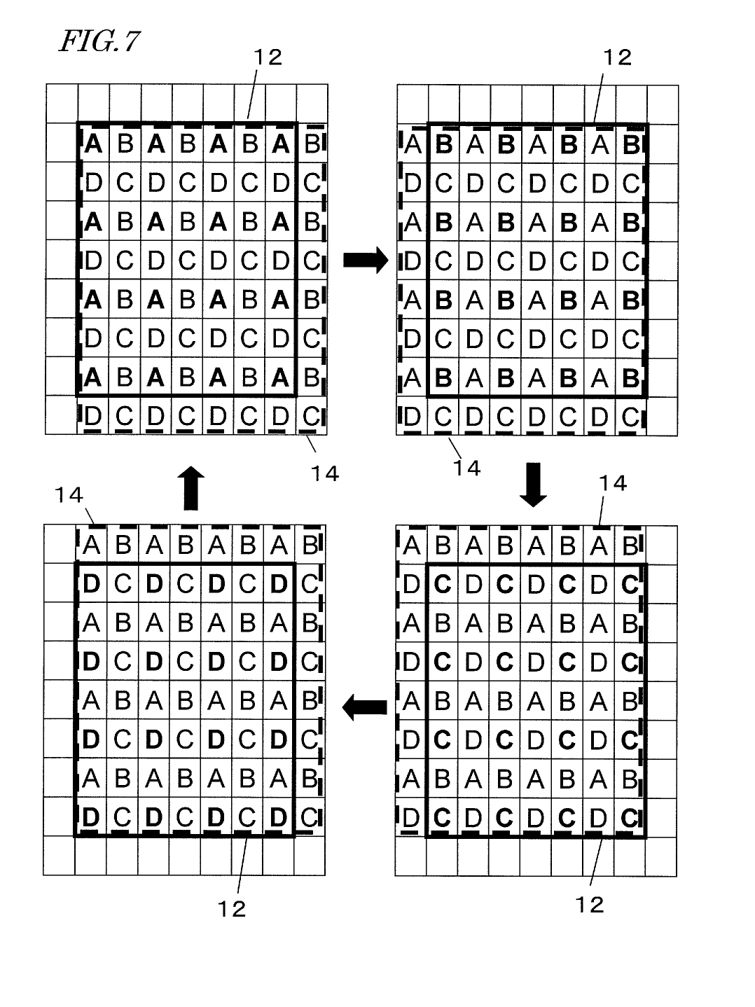

Hereinafter, the shift pattern of the polarizer array 14 will be described with reference to FIG. 7. Although only four polarizers included in a single unit structure are illustrated in FIGS. 3A through 3E, a lot of polarizers included in a single polarizer array 14 are illustrated in FIG. 7. Naturally, the number of polarizers included in the polarizer array 14 is actually far greater than the illustrated one.

In the example illustrated in FIG. 7, the bold rectangle indicates the photosensitive cell array 12 and the dashed rectangle indicates the polarizer array 14. With respect to the photosensitive cell array 12, the polarizer array 14 moves periodically between four different positions. In any case, no matter where the polarizer array 14 is located, each photosensitive cell is always covered with its associated polarizer.

In the example illustrated in FIG. 7, the size of the polarizer array 14 is bigger than that of the image capturing area and the number of polarizers that form the polarizer array 14 is larger than that of photosensitive cells that form the photosensitive cell array 12. However, the size of the polarizer array 14 does not always have to be bigger than that of the image capturing area. If the size of the polarizer array 14 is equal to or smaller than that of the image capturing area, there are some photosensitive cells that are not covered with the polarizer array 14. No polarization information can be obtained from such photosensitive cells. However, sometimes polarization information does not have to be obtained from the entire area of the subject. In that case, part of the photosensitive cell array 12 may be covered with a relatively small polarizer array 14. That is why the size of the polarizer array 14 could be smaller than that of the photosensitive cell array 12.

Next, the shifter 16 will be described.

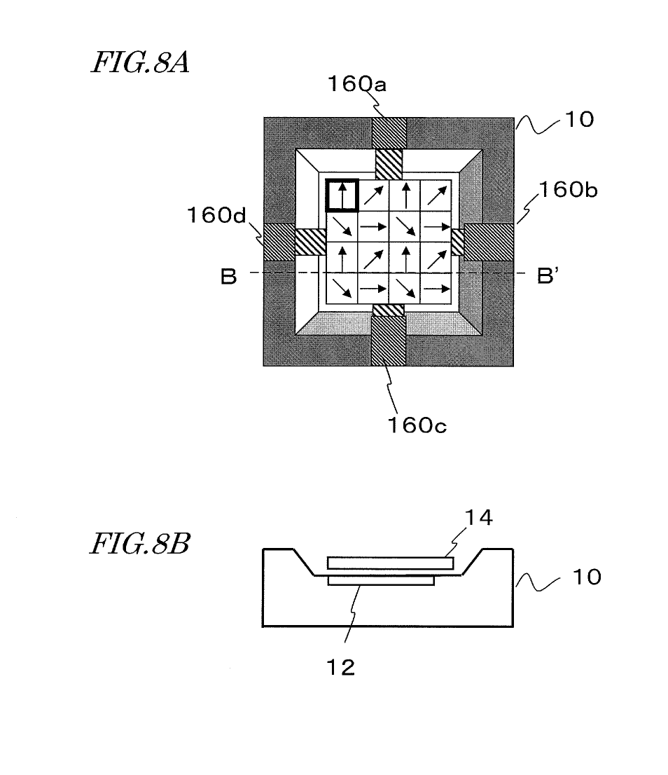

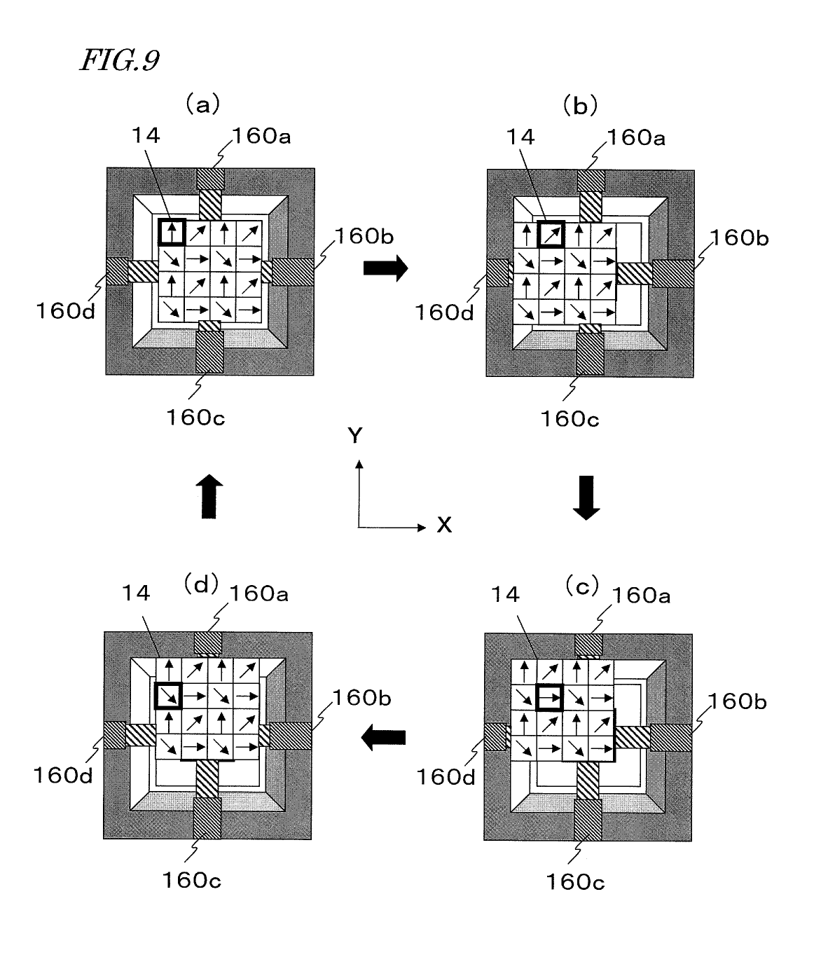

To translate the polarizer array 14 as shown in FIG. 7, the shifter 16 needs to have a structure that moves the point of application along the two axes, i.e., in the X- and Y-axis directions. FIG. 8 illustrates an example of an image sensor 10 in which such a structure forms an integral part of the silicon substrate of the photosensitive cell array 12. Specifically, FIGS. 8A and 8B are respectively a top view and a cross-sectional view of the image sensor 10 shown in FIG. 8A as viewed on the plane B-B′.

The image sensor 10 shown in FIG. 8 includes piezoelectric transducers 160a and 160c that drive the polarizer array 14 in the Y-axis direction and piezoelectric transducers 160b and 160d that drive the polarizer array 14 in the X-axis direction. Using the pair of piezoelectric transducers 160a and 160c that drive the polarizer array 14 in the Y-axis direction, the polarizer array 14 can be shifted on a pixel-by-pixel basis in both of the +Y- and −Y-axis directions. Likewise, using the pair of piezoelectric transducers 160b and 160d that drive the polarizer array 14 in the X-axis direction, the polarizer array 14 can be shifted on a pixel-by-pixel basis in both of the +X- and −X-axis directions. The piezoelectric transducers 160a, 160b, 160c and 160d may be made of a piezoelectric material such as piezoelectric zirconate titanate (PZT), for example. By regulating the voltages applied to these piezoelectric transducers 160a, 160b, 160c and 160d, the position of the polarizer array 14 can be changed periodically within the XY plane as shown in FIG. 7, for example. In this case, the piezoelectric transducers 160a, 160b, 160c and 160d together form the shifter 16.

Next, it will be described with reference to portions (a) through (d) of FIG. 9 how the shifter 16 operates in this example.

Suppose the polarizer array 14 is located at the position shown in portion (a) of FIG. 9 first. In that case, voltages are applied to the piezoelectric transducers 160a and 160d but no voltages are applied to the piezoelectric transducers 160b and 160c.

Next, at the position shown in portion (b) of FIG. 9, voltages are applied to the piezoelectric transducers 160a and 160b but no voltages are applied to the piezoelectric transducers 160c and 160d.

Then, at the position shown in portion (c) of FIG. 9, voltages are applied to the piezoelectric transducers 160b and 160c but no voltages are applied to the piezoelectric transducers 160a and 160d.

Subsequently, at the position shown in portion (d) of FIG. 9, voltages are applied to the piezoelectric transducers 160c and 160d but no voltages are applied to the piezoelectric transducers 160a and 160b.

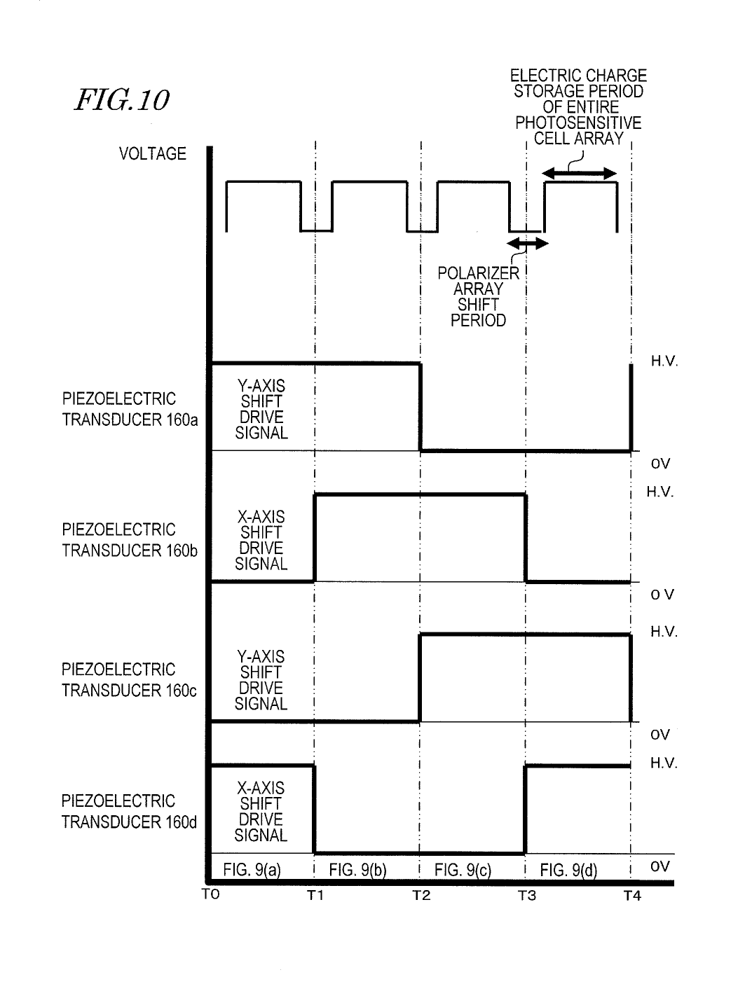

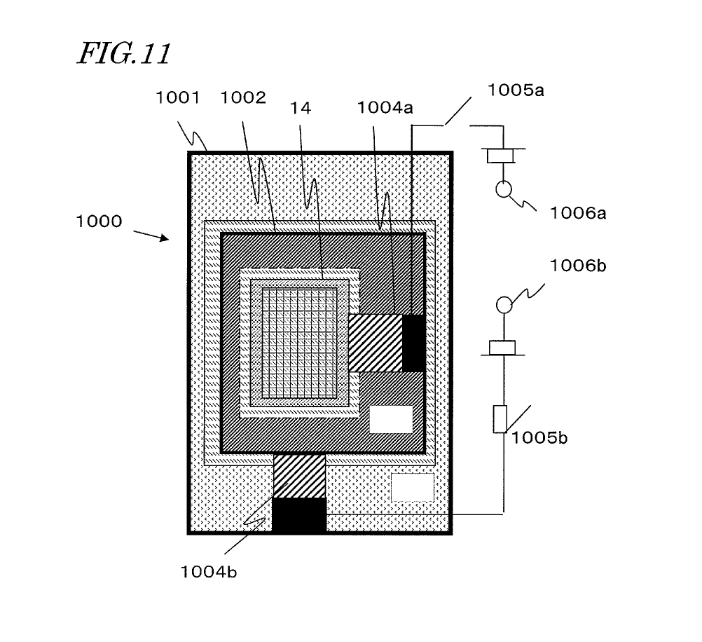

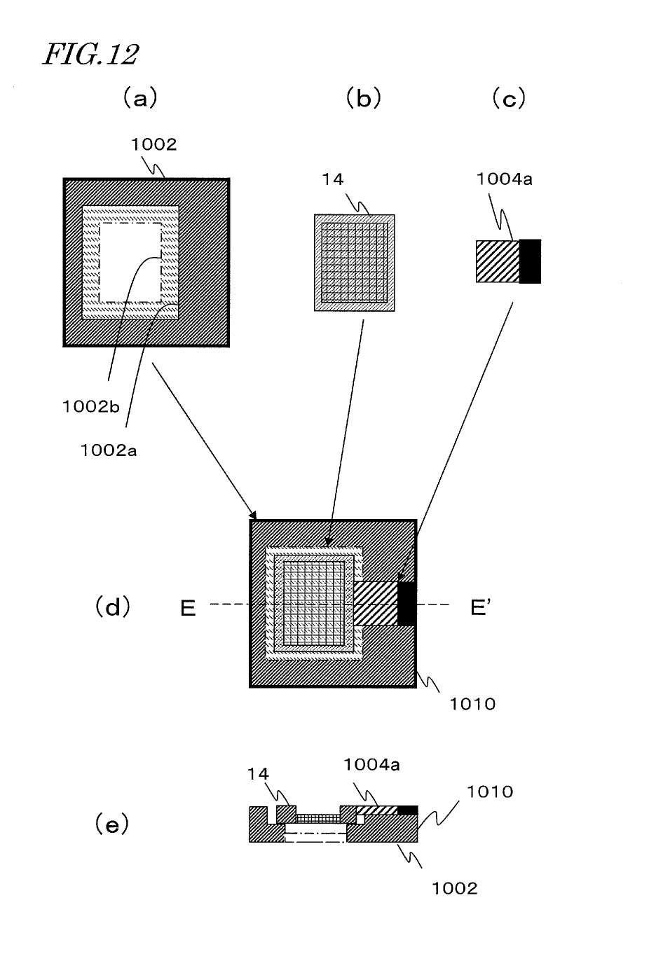

If the voltages are applied to those piezoelectric transducers 160a, 160b, 160c and 160d as shown in the timing diagram of FIG. 10, the positions of the polarizers 14 can be controlled on a pixel-by-pixel basis in the X- and Y-axis directions as shown in portions (a), (b), (c) and (d) of FIG. 9 in this order.

To get that pixel-by-pixel shifting done, the axial size of the piezoelectric body to use and the applied voltage may be adjusted. For example, if the size of a single pixel is 25 μm×25 μm, the pixel pitches in the X and Y directions are both 25 μm. To get shifting by one pixel (25 μm) done using PZT in that case, the axial size of PZT may be set to be approximately 5 mm, for example. If the size of one pixel is 25 μm×25 μm, the size of a photodiode in that pixel may be defined by a diameter of about 5 μm, for example. In that case, the size of its associated polarizer is preferably set to be larger than that of the photodiode. It should be noted that the arrangement pitch of polarizers is set to be equal to that of pixels in the photosensitive cell array irrespective of the size of the respective polarizers.

FIG. 10 is a diagram showing exemplary waveforms of voltages to be applied to those piezoelectric transducers 160a, 160b, 160c and 160d when the series of operations described above are performed. In FIG. 10, also shown schematically is the electric charge storage period of the entire photosensitive cell array 12 that has already been described with reference to FIG. 28. The polarizer array 14 is shifted two-dimensionally by the piezoelectric transducers 160a through 160d within a period other than the electric charge storage period.

As shown in FIG. 10, in the beginning, the voltages applied to the piezoelectric transducers 160b and 160c are both 0 V but the voltages applied to the piezoelectric transducers 160a and 160d are both several hundred V (at the time T0). Next, when shifting is done by one pixel in the X-axis direction (at the time T1), the voltages applied to the piezoelectric transducers 160c and 160d are both 0 V but a high voltage (of 100 V, for example) is applied to the piezoelectric transducers 160a and 160b. After that (at the time T2), the voltages applied to the piezoelectric transducers 160a and 160d are both 0 V but a high voltage (of 100 V, for example) is applied to the piezoelectric transducers 160b and 160c. Subsequently, at the time T3, the voltages applied to the piezoelectric transducers 160a and 160b are both 0 V but the voltages applied to the piezoelectric transducers 160c and 160d change into several hundred V. Thereafter, at the time T4, the voltages applied to these piezoelectric transducers 160a, 160b, 160c and 160d are restored into the levels at the time T0 again, thereby recovering the initial state in one period.

It should be noted that as a piezoelectric transducer generally has hysteresis, the piezoelectric transducer sometimes does not recover its original state even if the voltage that was applied to the piezoelectric transducer stretching is restored into zero volts. That is why to return the piezoelectric transducer to its original position accurately, a voltage, of which the magnitude has been corrected in view of the hysteresis, needs to be applied.

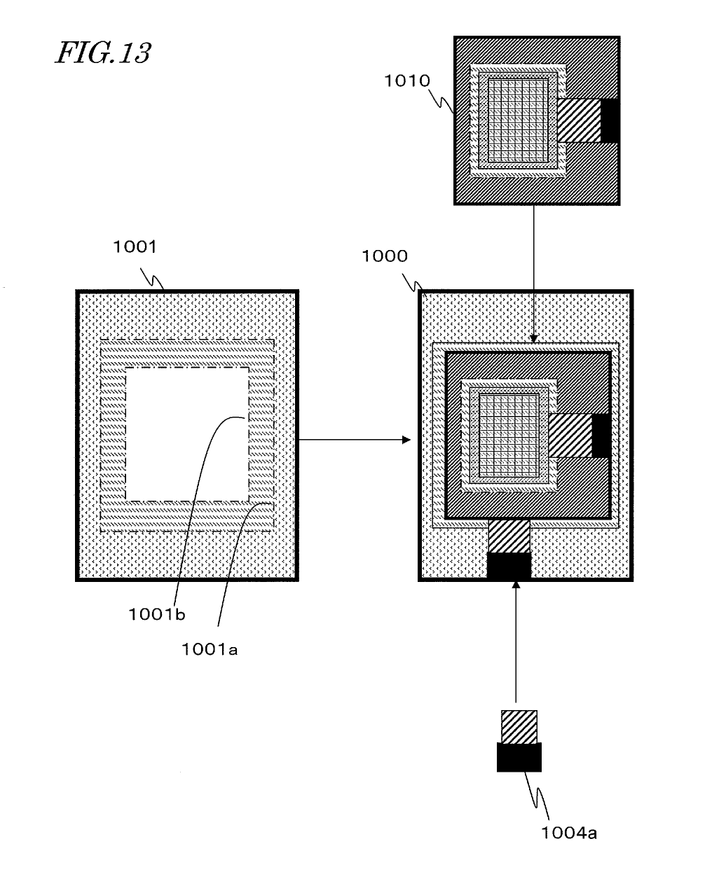

FIG. 11 is a top view illustrating a movable polarizer unit 1000 in which the shifter 16 and the polarizer array 14 are integrated together.

This movable polarizer unit 1000 includes a base 1002 with a linear actuator 1004a that shifts the polarizer array 14 in the X-axis direction and another base 1001 with another linear actuator 1004a that shifts the former base 1002 in the Y-axis direction. The linear actuator 1004a is connected to a high voltage source 1006a via a switch 1005a. On the other hand, the linear actuator 1004b is connected to another high voltage source 1006b via another switch 1005b. By opening and closing the switches 1005a and 1005b, the voltages applied to the linear actuators 1004a and 1004b can be controlled and the polarizer array 14 can be shifted within the XY plane.

Portions (a), (b) and (c) of FIG. 12 are top views of the base 1002, the polarizer array 14 and the linear actuator 1004a, respectively. The base 1002 has a recess 1002a and an opening 1002b, and is preferably obtained by patterning a silicon substrate. The recess 1002a has a shape and a size that are determined to house the polarizer array and allow the polarizer array 14 to shift in the X direction. The opening 1002b may have a size of approximately 25 mm square. By combining these members together, the X direction shifting stage 1010 shown in portion (d) of FIG. 12 can be obtained. Portion (e) of FIG. 12 is a cross-sectional view of the X direction shifting stage shown in portion (d) of FIG. 12 as viewed on the plane E-E′. Each of the multiple polarizers in the polarizer array 14 may be made of a photonic crystal or a nanowire grid, for example.

By combining the X direction shifting stage 1010 with the base 1001 and linear actuator 1004a shown in FIG. 13, the shifter 16 is obtained. The base 1001 has a recess 1001a and an opening 1001b. The recess 1001a has a shape and a size that are determined to house the X direction shifting stage 1010 and allow the stage 1010 to shift in the Y direction. The base 1001 is also preferably obtained by patterning a silicon substrate. The respective openings 1001b and 1002b of these bases 1001 and 1002 are provided to make the light that has been transmitted through the polarizer array 14 incident on the photosensitive cell array 21 (not shown). To make incident only light rays that have been transmitted through polarizers that are associated with respective photosensitive cells, the gap between the photosensitive cell array 12 and the polarizer array 14 is preferably set to be 1 mm or less.

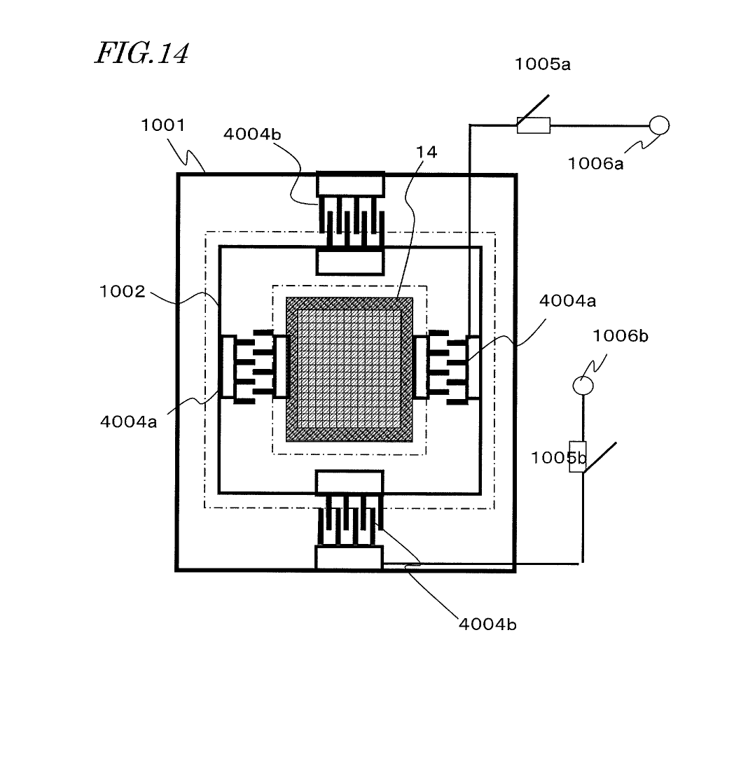

FIG. 14 is a top view illustrating still another exemplary configuration for the shifter 16. Unlike the shifter 16 shown in FIG. 11, this shifter 16 uses comb MEMS (micro-electro-mechanical systems) actuators 4004a and 4004b instead of the linear actuators 1004a and 1004b. By applying voltages to the pair of comb electrodes of the comb MEMS actuators 4004a and 400b that face each other, the actuators 4004a and 400b can shift the polarizer array 14 with the electrostatic force generated.

The mechanism for shifting the polarizer array within a plane that is parallel to the image capturing area does not have to be one of the examples described above. Rather, a mechanism that operates based on any other principle may also be used as long as the polarizer array can be shifted accurately on a pixel-by-pixel basis.

The “positioning precision” of such an actuator that can be used to realize as short a shift distance as one pixel size may be set to be approximately 5% or less of that shift distance. The size of the photosensitive cells is determined in view of such positioning precision so that all of those photosensitive cells are covered with the polarizers.

The “unit structures” in the polarizer array do not have to have a square shape. The number of polarizers that form one “unit structure” does not have to be three or four, either, and may also be two, five or more.

<Image Capture Device>

Hereinafter, a configuration for an image capture device as a preferred embodiment of the present invention will be described.

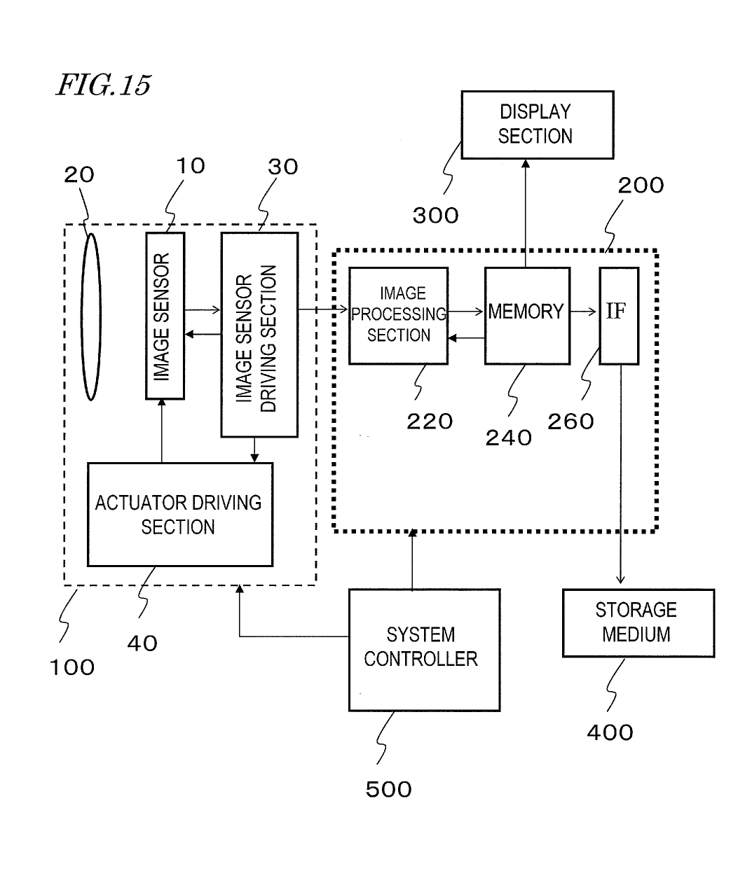

FIG. 15 is a block diagram illustrating a general configuration for an image capture device as a preferred embodiment of the present invention.

The image capture device of this preferred embodiment includes an image capturing section 100, a signal processing section 200 that performs various kinds of signal processing, a captured image display section 300 that displays the image captured, a storage medium 400 that stores the image data, and a system control section 500 that controls the respective sections.

The image capturing section 100 of this preferred embodiment includes an imager (image sensor) 10 including the polarizer array 14 and the shifter 16 and a shooting lens 20 that produces an image on the image capturing plane of the image sensor 10. The shooting lens 20 of this preferred embodiment has the known structure and is actually implemented as a lens unit that is made up of multiple lenses. The shooting lens 20 is driven by a mechanism (not shown) to carry out operations to get optical zooming, auto-exposure (AE), and auto-focusing (AF) done as needed.

The image capturing section 100 further includes an image sensor driving section 30 that drives the image sensor and an actuator driving section 40. The image sensor driving section 30 may be implemented as a driver LSI, for example. The image sensor driving section 30 drives the image sensor 10, thereby reading an analog signal from the image sensor 10 and converting the analog signal into a digital signal. The actuator driving section 40 drives the shifter 16 described above, thereby shifting the polarizer array 14 periodically within a plane that is parallel to the image capturing area.

The signal processing section 200 of this preferred embodiment includes an image processing section (image processor) 220, a memory 240 and an interface (IF) section 260, and is connected to the display section 300 such as an LCD panel and to the storage medium 400 such as a memory card.

The image processing section 220 carries out not only various kinds of signal processing to get color tone correction, resolution change, auto-exposure, auto-focusing, data compression and other operations done but also the polarization information obtaining processing of the present invention. The image processing section 220 is preferably implemented as a combination of a known digital signal processor (DSP) or any other piece of hardware and a software program that is designed to perform image processing including the polarization information processing of the present invention. The memory 240 may be a DRAM, for example. The memory 240 not only stores the image data provided by the image capturing section 100 but also temporarily retains the image data that has been subjected to the various kinds of image processing by the image processing section 220. Those image data are either converted into an analog signal and then displayed on the display section 300 or written as a digital signal on the storage medium 400 by way of the interface section 260.

All of these components are controlled by the system control section 500 including a central processing unit (CPU) and a flash memory, none of which are shown in FIG. 15. Actually, the image capture device of this preferred embodiment further includes a viewfinder, a power supply (or battery), a flashlight and other known members. However, description thereof will be omitted herein because none of those members are essential ones that would make it difficult to understand how the present invention works unless they were described fully.

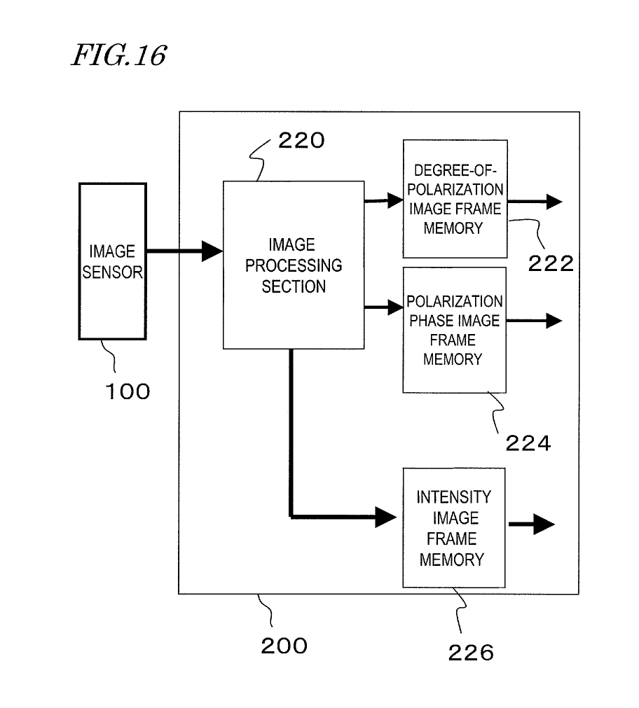

FIG. 16 is a block diagram illustrating an exemplary combination of major components of the signal processing section 200 of this preferred embodiment. According to this preferred embodiment, polarization image information can be obtained from the subject and output as two different kinds of polarization images (namely, a degree-of-polarization image ρ and a polarization phase image φ).

The output signal of the image capturing section 100 is supplied to, and processed by, the image processing section 220, and then stored in a degree-of-polarization image frame memory 222 and a polarization phase image frame memory 224. The degree-of-polarization image frame memory 222 outputs data of the degree-of-polarization image (ρ) and the polarization phase image frame memory 224 outputs data of the polarization phase image (φ).

<Polarization Information>

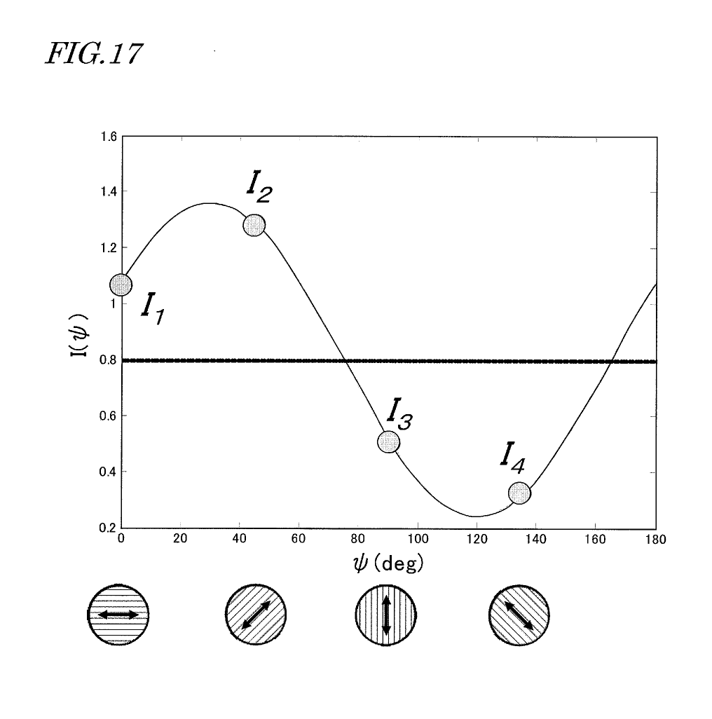

FIG. 17 shows the intensities (either pixel values or luminances) I₁ through I₄ of the light rays that have been transmitted through four kinds of polarizers, of which the polarization transmission axes (with Ψi=0, 45, 90, and 135 degrees, respectively) are defined in four different directions. In this example, if the angle of rotation φ of the polarization main axis is φᵢ, then the intensity measured will be identified by Iᵢ, where i is an integer that falls within the range of 1 to N and N is the number of samples. In this example, N=4, and therefore, i==1, 2, 3 or 4. In FIG. 17, the intensities I₁ through I₄ associated with the four samples (φᵢ, Iᵢ) obtained from a single pixel are shown. The relation between the angle Ψi of the polarization main axis and the intensities Iᵢ is represented by a sinusoidal function with a period π (180 degrees). A sinusoidal function with a fixed period has only three kinds of unknowns, i.e., amplitude, phase and average. That is why by measuring the three intensities Iᵢ at mutually different angles ψ, a single sinusoidal curve can be determined completely.

The intensity measured on a polarizer unit with respect to the polarization main axis angle ψ is represented by the following Equation (1):

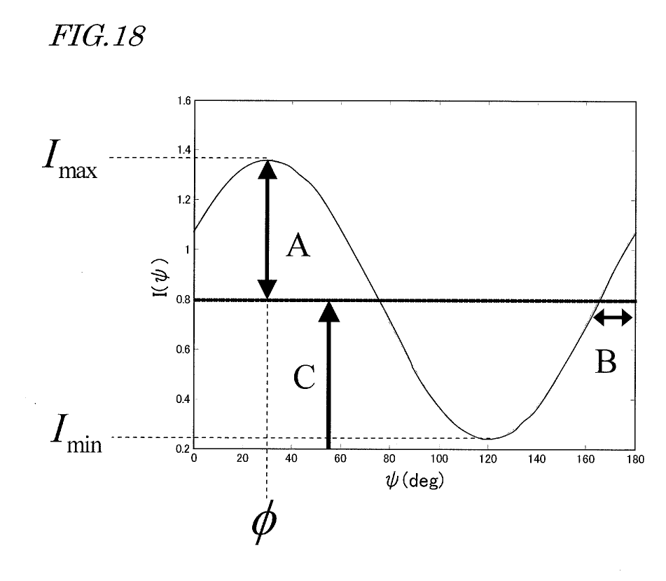

I(ψ)=A·sin 2(ψ−B)+C (1)

where A, B and C are unknown constants as shown in FIG. 18 and respectively represent the amplitude, phase and average of the curve showing a variation in polarized light intensity.

In this description, the “polarization information” means information about the degree of modulation of the amplitude ρ of such a sinusoidal curve, representing the fluctuation of the intensity according to the angle of the polarization main axis, and the phase information φ thereof. By performing these processing steps, the three parameters A, B and C of the sinusoidal function are determined. In this manner, a degree-of-polarization image representing the degree of polarization ρ and a polarization phase image representing the polarization phase φ can be obtained for each pixel. Specifically, the degree of polarization ρ represents how much the light in a pixel of interest has been polarized, while the polarization phase φ represents an angular position at which the sinusoidal function has the maximum value. It should be noted that the polarization main axis angles of 0 and 180 degrees (π) are the same as each other.

The values ρ and φ (where 0≦φ≦π) are calculated by the following Equations (2) and (3), respectively:

$$\begin{matrix}ρ = \frac{{I}_{ma x} - {I}_{m i n}}{{I}_{ma x} + {I}_{m i n}} = \frac{A}{C} & ( 2 ) \\ φ = \frac{π}{4} + B & ( 3 )\end{matrix}$$

In this manner, according to this preferred embodiment, polarization information can be obtained from every pixel based on the pixel value that has been read with the polarizer array 14 shifted.

### Embodiment 2

Hereinafter, a second preferred embodiment of an image sensor according to the present invention will be described.

The image sensor of this second preferred embodiment is different from the counterpart of the first preferred embodiment described above only in the arrangement pattern of polarizers in the polarizer array and how to shift the polarizer array. Thus, the following description of the second preferred embodiment will be focused on just these differences from the first preferred embodiment and their common configuration or operation will not be described all over again.

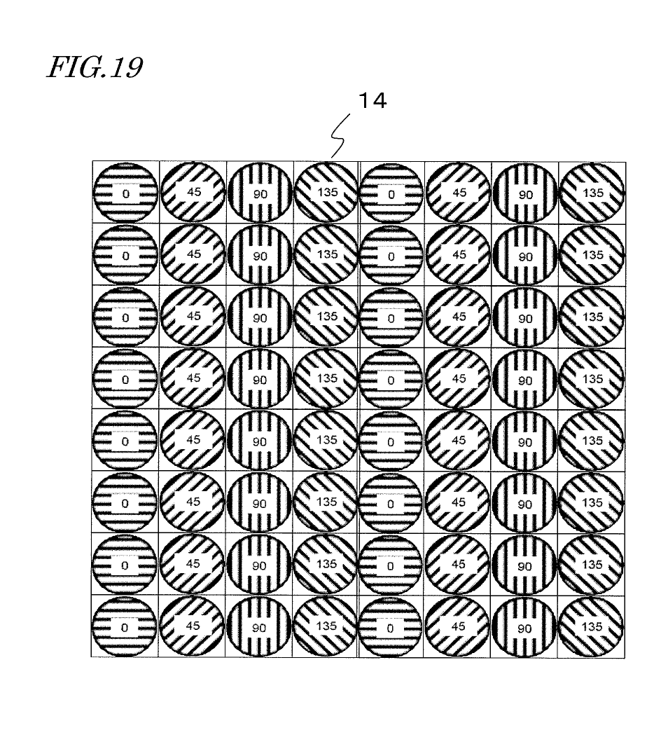

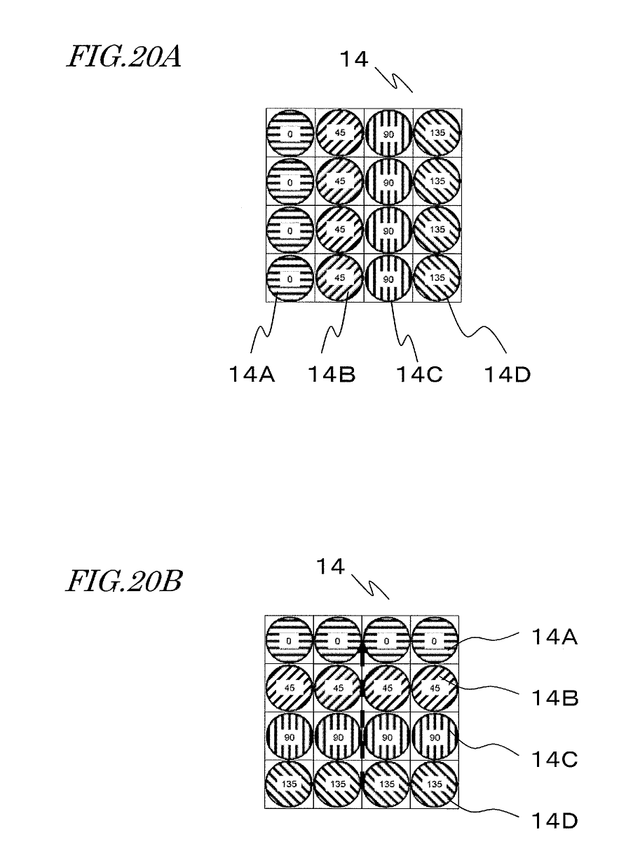

FIG. 19 is a top view illustrating the arrangement of the polarizer array of this preferred embodiment. In this polarizer array, four kinds of polarizers, which have mutually different polarization transmission axes, are arranged in stripes. FIG. 20A illustrates a part of the polarizer array shown in FIG. 19 and FIG. 20B illustrates an alternative arrangement pattern of polarizers. Both of the arrangement patterns shown in FIGS. 20A and 20B may be adopted. In the following example, however, it will be described how the image sensor operates when the arrangement pattern shown in FIG. 20A is adopted.

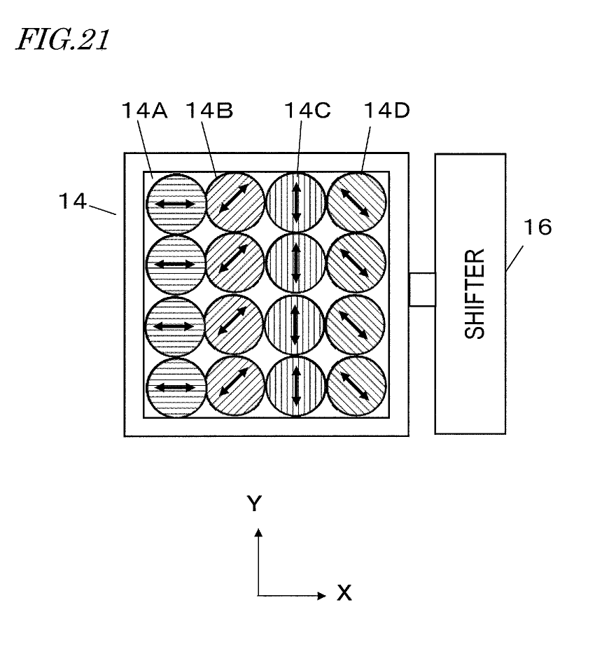

According to this preferred embodiment, a polarizer array 14, each row of which includes four different kinds of polarizers 14A, 14B, 14C and 14D, can be shifted on a pixel-by-pixel basis by the shifter 16 as shown in FIG. 21.

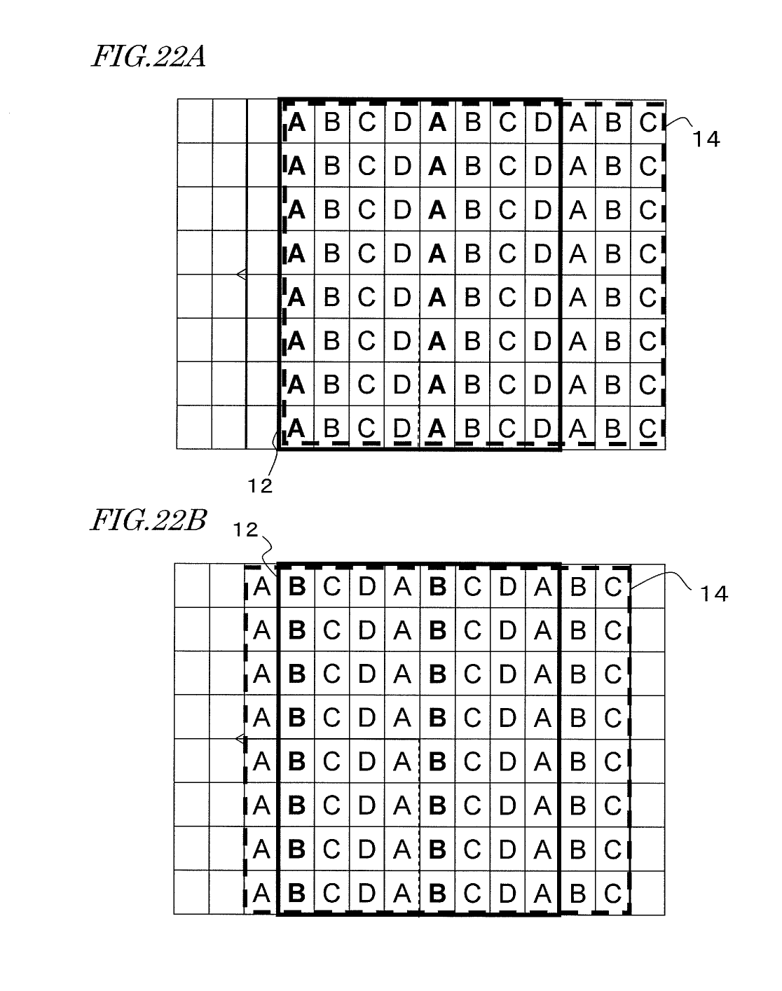

Suppose this polarizer array 14 is located at the position shown in FIG. 22A in the beginning. Next, the polarizer array is shifted by the shifter 16 in the X-axis direction to the position shown in FIG. 22B.

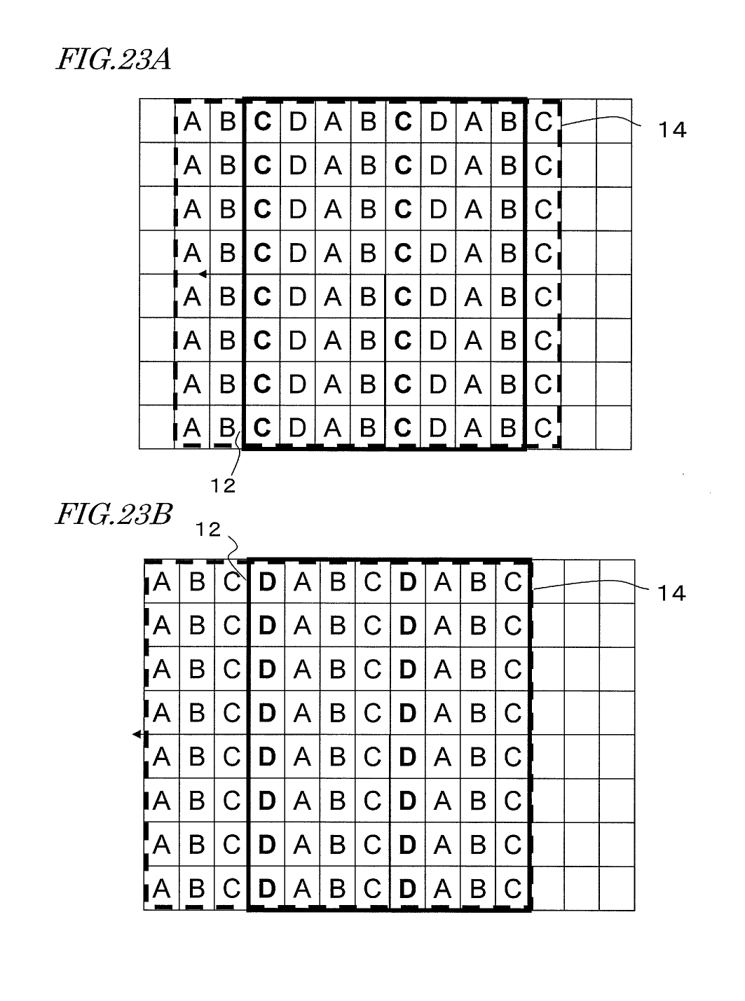

Subsequently, the polarizer array 14 is further shifted by the shifter 16 in the X-axis direction to the position shown in FIG. 23A. Thereafter, the polarizer array is further shifted by the shifter 16 in the X-axis direction to the position shown in FIG. 23B.

And then the polarizer array 14 is shifted back in the opposite direction by three pixels and returned to the original position shown in FIG. 22A. By repeatedly performing these periodic operations, polarization information can be obtained.

According to this preferred embodiment, the polarizer array 14 needs to be shifted in only one direction within the XY plane, and therefore, the shifter 16 can have a simplified configuration. Although the polarizer array 14 is supposed to be shifted in the X-axis direction in the example described above, the polarizer array 14 may also be shifted in the Y-axis direction. Furthermore, similar effects can also be achieved even by shifting linearly the polarizer array in such a direction that obliquely intersects with both of the X- and Y-axis directions.

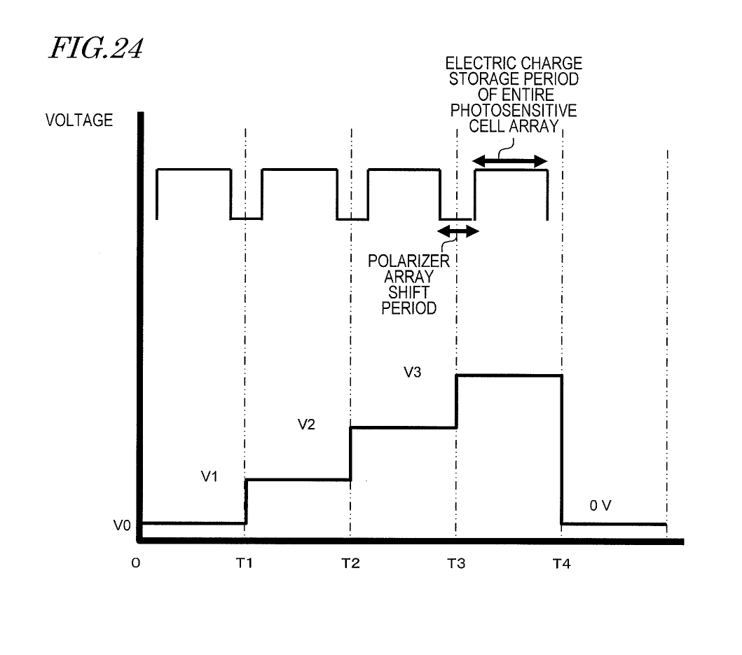

FIG. 24 is a diagram showing an exemplary waveform of the voltages applied to the actuator when the series of operations described above are carried out. As shown in FIG. 24, even though the voltage applied to the actuator is 0 V in the beginning, a voltage V1 (of 100 V, for example) is applied to the actuator when the polarizer array needs to be shifted by one pixel in the X-axis direction (at the time T1). Next, when the polarizer array needs to be shifted by two pixels from the initial position (at the time T2), a voltage V2 (of 200 V, for example) is applied to the actuator. Subsequently, when the polarizer array needs to be shifted by three pixels from the initial position (at the time T3), a voltage V3 (of 300 V, for example) is applied to the actuator. And then by lowering the voltage applied to the actuator all the way down to 0 V (at the time T4), the actuator can recover its initial state.

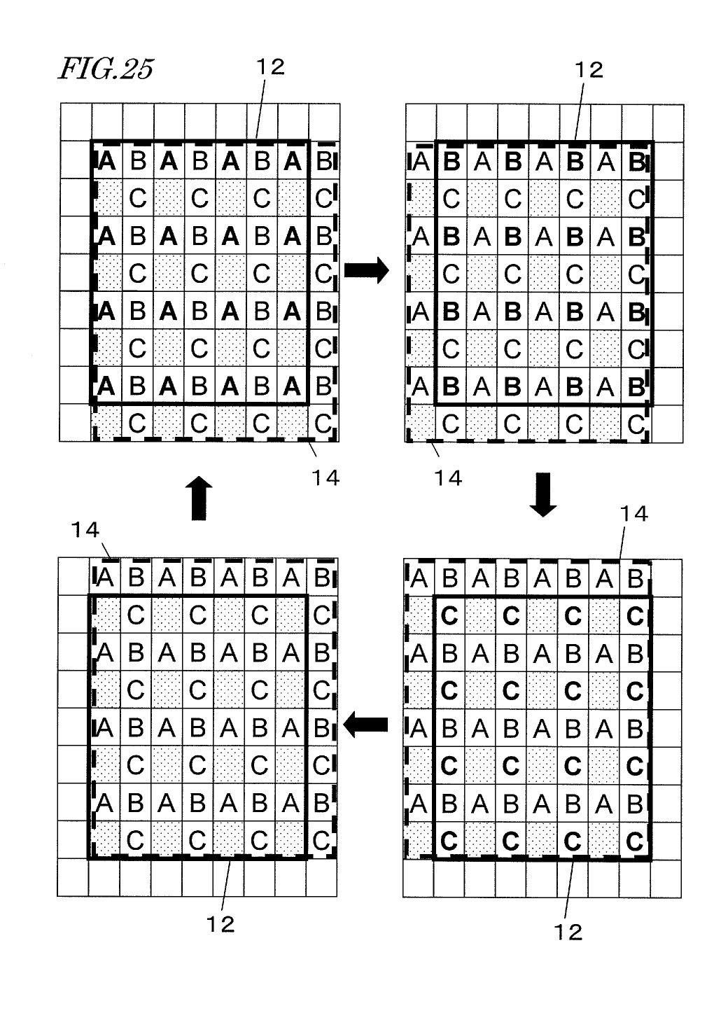

In the preferred embodiment described above, the four kinds of polarizers 14A, 14B, 14C and 14D are arranged in the same polarizer array 14 so that their polarization transmission axes point four different directions. However, the present invention is in no way limited to that specific preferred embodiment. As already described with reference to FIG. 17, in order to obtain a sinusoidal wave that defines the polarization information, the polarization transmission axes may be defined by at least three different angles. FIG. 25 illustrates how to shift a polarizer array 14 where three kinds of polarizers 14A, 14B and 14C, of which the polarization transmission axis directions are different from each other by 60 degrees, are arranged. Although no polarizers are arranged in some regions of this polarizer array, its shift pattern is the same as what is illustrated in FIG. 7. As a result, light rays that have been transmitted through those regions with no polarizers are also incident on the pixels. When a light ray that has been transmitted through such a region with no polarizer is incident on a pixel, a luminance signal representing a non-polarized light ray can be obtained from that pixel.

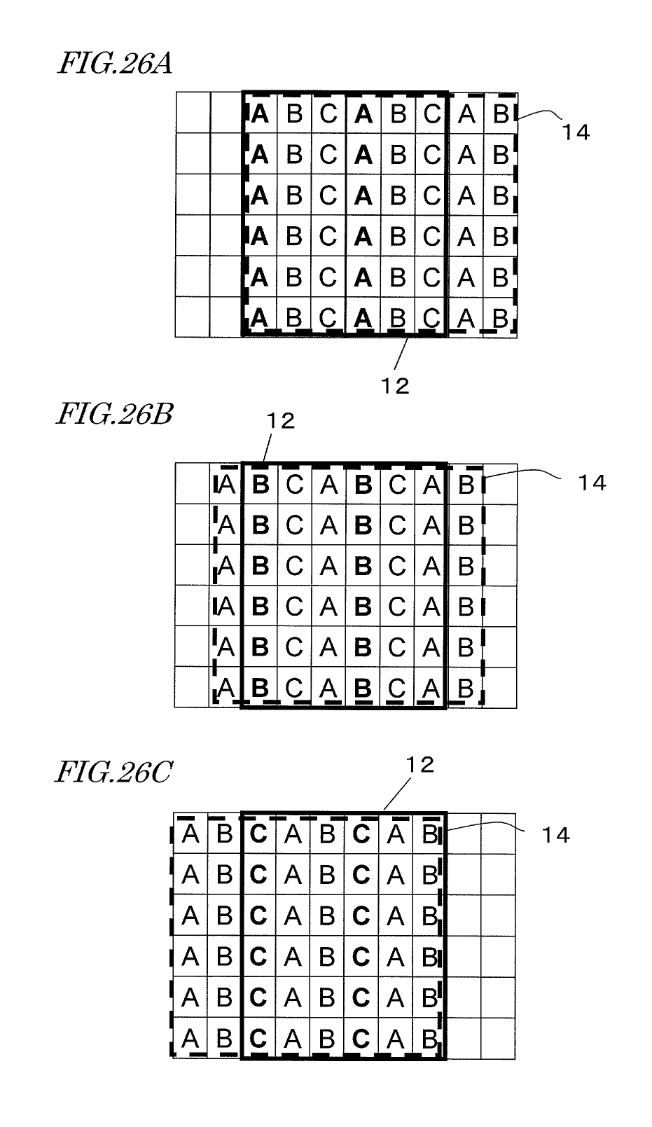

FIGS. 26A through 26C illustrate an example in which a polarizer array 14 where three kinds of polarizers 14A, 14B and 14C are arranged is shifted only in the X-axis direction. In this case, the polarizer array 14 does not have any pixel region with no polarizers, and therefore, a light ray that has been transmitted through a polarizer is incident on each pixel. If such a polarizer array is used, one period of pixel shifting can have a shorter stroke. As a result, the size of the actuator can be reduced easily, which is beneficial.

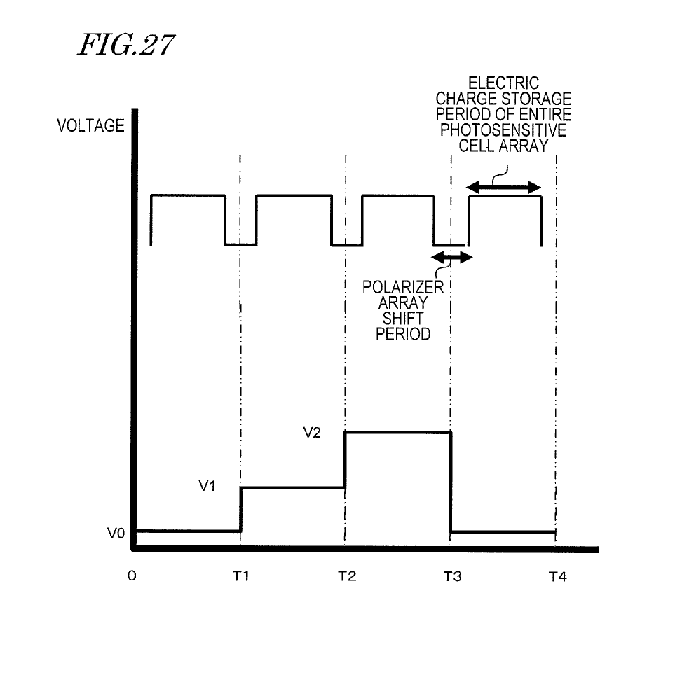

If the operations shown in FIGS. 26A through 26C are performed, the voltages applied to the actuator may have the waveform shown in FIG. 27, for example.

In the various preferred embodiments of the present invention described above, in order to obtain polarization information from each pixel, multiple different kinds of polarizers, of which the polarization transmission axes point three or four different directions, are sequentially arranged on the respective photosensitive cells, thereby reading out pixel signals (or sample values). However, the present invention is in no way limited to those specific preferred embodiments. The effect of the present invention can also be achieved even with an arrangement in which light rays that have been transmitted through only two kinds of polarizers, of which the polarization transmission axes point two different directions, are incident on respective photosensitive cells. In that case, three parameters that determine the light intensity variation curve such as the one shown in FIG. 18 cannot be identified. Nevertheless, orthogonal polarization components can still be detected, which is advantageous in the field of technology of endoscopes, for example.

The image sensor and image capture device of the present invention are applicable to various fields of polarization imaging technologies, and can be used effectively as a key device for the purposes of security, medical treatment, telecommunication, and analysis.

While the present invention has been described with respect to preferred embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

What is claimed is:

1. An image sensor comprising:
a photosensitive cell array in which a plurality of photosensitive cells are arranged on an image capturing plane;
a polarizer array in which a plurality of unit structures, each including N polarizers (where N is an integer that is equal to or greater than two) that have mutually different polarization transmission axis directions, are arranged two-dimensionally, the polarizer array being configured to allow light that is transmitted through each said polarizer to be incident on its associated photosensitive cell;
a circuit configured to read a pixel signal from the photosensitive cell array; and
an actuator configured to shift the polarizer array with respect to the photosensitive cell array parallel to the image capturing plane.

2. The image sensor of claim 1, wherein when an image is being captured, the actuator shifts the polarizer array by a distance that does not exceed the size of the unit structure.

3. The image sensor of claim 1, wherein when a stored electric charge signal is read from the entire photosensitive cell array, the actuator shifts the polarizer array on a pixel-by-pixel basis, thereby changing the polarization direction of light that is going to be incident on each said photosensitive cell.

4. The image sensor of claim 1, wherein the image sensor is configured to perform:
making light that has been transmitted through one of the N polarizers incident on each said photosensitive cell; and
shifting the polarizer array on a pixel-by-pixel basis and then making light that has been transmitted through another one of the N polarizers incident on the photosensitive cell.

5. The image sensor of claim 1, wherein the actuator includes a first actuator portion configured to shift the polarizer array in a first direction on a pixel-by-pixel basis and a second actuator portion configured to shift the polarizer array in a second direction on a pixel-by-pixel basis, the second direction being perpendicular to the first direction, and
wherein the actuator is configured to shift the polarizer array periodically and two-dimensionally on the image capturing plane.

6. The image sensor of claim 1, wherein N is equal to or greater than three.

7. The image sensor of claim 1, wherein the actuator is configured to move the polarizer array periodically and linearly on the image capturing plane.

8. The image sensor of claim 1, wherein the arrangement pitch of the polarizers in the polarizer array equals to the arrangement pitch of the photosensitive cells in the photosensitive cell array.

9. The image sensor of claim 1, wherein each of the unit structures includes four polarizers, the polarization transmission axis directions of the four polarizers being different from each other by 45 degrees.

10. The image sensor of claim 1, wherein each of the unit structures includes three polarizers, the polarization transmission axis directions of the three polarizers are different from each other by 60 degrees.

11. An image capture device comprising:
an image sensor that includes a photosensitive cell array in which a plurality of photosensitive cells are arranged on an image capturing plane, a polarizer array in which a plurality of unit structures, each including N polarizers (where N is an integer that is equal to or greater than two) that have mutually different polarization transmission axis directions, are arranged two-dimensionally and which is arranged so that light that is transmitted through each said polarizer is incident on its associated photosensitive cell, and an actuator configured to shift the polarizer array with respect to the photosensitive cell array parallel to the image capturing plane;
a driver configured to drive the actuator; and
a shooting lens configured to produce an image on the image sensor.

12. The image sensor of claim 11, wherein when a stored electric charge signal is read from the entire photosensitive cell array, the actuator shifts the polarizer array on a pixel-by-pixel basis, thereby changing the polarization direction of light that is going to be incident on each said photosensitive cell and obtaining luminance values of light rays that have been incident on respective photosensitive cells with mutually different polarization directions.
